(19) United States
(12) Patent Application Publication
(10) Pub. No.: US 2011/0265297 A1
(43) Pub. Date: Nov. 3, 2011

(54) Method of manufacturing inkjet head

(75) Inventors: Pil Joong Kang, Suwon (KR); Yoon Sok Park, Suwon (KR); Suk Ho Song, Ansan (KR); Jae Woo Joung, Suwon (KR)

(73) Assignee: SAMSUNG ELECTRO-MECHANICS CO., LTD., Suwon (KR)

(21) Appl. No.: 13/064,569

(22) Filed: Mar. 31, 2011

(30) Foreign Application Priority Data
Apr. 30, 2010 (KR) 10-2010-0040464

(51) Int. Cl. B41J 2/025; H01L 41/22

(52) U.S. Cl. 29/25.35; 29/890.1

(57) ABSTRACT

There is provided a method of manufacturing an inkjet head. A method of manufacturing an inkjet head according to an aspect of the invention may include: forming a piezoelectric actuator on a dummy substrate; cutting the piezoelectric actuator into head cell units of an inkjet head; preparing an inkjet head substrate including an ink chamber formed at a position corresponding to the piezoelectric actuator; bonding the dummy substrate and the inkjet head substrate to each other so that the piezoelectric actuator and the ink chamber correspond to each other; and removing the dummy substrate.

### CROSS-REFERENCE TO RELATED APPLICATIONS

This application claims the priority of Korean Patent Application No. 10-2010-0040464 filed on Apr. 30, 2010, in the Korean Intellectual Property Office, the disclosure of which is incorporated herein by reference.

### BACKGROUND OF THE INVENTION

1. Field of the Invention

The present invention relates to a method of manufacturing an inkjet head, and more particularly, to a method of manufacturing an inkjet head having improved productivity and processing precision for a piezoelectric actuator by manufacturing a piezoelectric actuator, providing a driving force allowing an inkjet head to eject ink, at wafer level.

2. Description of the Related Art

In general, an inkjet head converts an electric signal into a physical force so that ink droplets are ejected through small nozzles. An inkjet head can be divided into two types according to its ink ejection method: a thermally driven type inkjet head and a piezoelectric type inkjet head. A thermally driven type inkjet head generates bubbles in ink by using a heat source to eject the ink by the expansion force of the bubbles. A piezoelectric type inkjet head uses a piezoelectric material and ejects ink by pressure being exerted on the ink due to the distortion of the piezoelectric material.

In particular, piezoelectric type inkjet heads have come into widespread use in industrial inkjet printers. For example, a circuit pattern is directly formed by spraying ink prepared by melting metals such as gold or silver onto a printed circuit board (PCB). A piezoelectric inkjet head is also used for industrial graphics, and is used in the manufacturing of a liquid crystal display (LCD) and an organic light emitting diode (OLED), or is used for the production of solar cells, and the like.

A piezoelectric actuator is formed in a piezoelectric type inkjet head by using a method including a process of forming a thick layer, such as screen printing, a method of bonding bulk ceramic materials in head chip unit, or the like.

However, according to the method including the process of forming a thick layer, a piezoelectric paste, coated to form a thick layer, is leveled over time and spread out due to the fluidity of the piezoelectric paste, which causes non-uniform width and thickness of the piezoelectric actuator, and lowers the piezoelectric performance of the piezoelectric actuator to be less than that of bulk ceramics.

Also, since bulk ceramics have a large thickness, it is difficult to process bulk ceramics by using a MEMS (microelectro-mechanical system) process. Also, bulk ceramic alignment errors may occur while bulk ceramics are bonded. In order to avoid damage to an inkjet head during a dicing process, the dicing process needs to be performed by a thickness smaller than that of the piezoelectric actuator, which causes processing errors. In addition, an inkjet head substrate may undergo flexural deformation caused by the dicing process. Besides, since a bulk ceramic bonding process is performed in the head chip unit, processing time is extended, which leads to decreased productivity such as a decrease in processing yield and an increase in manufacturing costs.

### SUMMARY OF THE INVENTION

An aspect of the present invention provides a method of manufacturing an inkjet head having improved productivity including a reduction in manufacturing costs, shortened processing time, and improved processing precision by creating uniform width and thickness in a piezoelectric actuator by bonding a piezoelectric actuator to an inkjet head at wafer level.

According to an aspect of the present invention, there is provided a method of manufacturing an inkjet head, the method including: forming a piezoelectric actuator on a dummy substrate; cutting the piezoelectric actuator into head cell units of an inkjet head; preparing an inkjet head substrate including an ink chamber formed at a position corresponding to the piezoelectric actuator; bonding the dummy substrate and the inkjet head substrate to each other so that the piezoelectric actuator and the ink chamber correspond to each other; and removing the dummy substrate.

The forming of the piezoelectric actuator on the dummy substrate may include: forming a film layer on the dummy substrate, the film layer having an opening in which the piezoelectric actuator is formed; inserting the piezoelectric actuator in the opening; and removing the film layer.

The film layer may be formed of one or more layers, and a lower layer of the film layer serves as an auxiliary cutting layer when the piezoelectric actuator is cut into head cell units of the inkjet head.

An alignment mark may be formed on the film layer to display a position of each individual head cell in the piezoelectric actuator.

The film layer may be formed of DFR (dry film resist).

The method may further include heating and pressurizing the dummy substrate and the piezoelectric actuator.

The method may further include polishing the piezoelectric actuator.

The method may further include cutting the piezoelectric actuator so that respective cut piezoelectric actuators are formed according to unit head cells of the inkjet head substrate.

The forming of the piezoelectric actuator on the dummy substrate may be performed by any one of sputtering, electron beam evaporation, thermal evaporation, screen printing and bulk ceramic bonding.

The piezoelectric actuator may include a driving electrode, a piezoelectric layer and a common electrode, and the driving electrode, the piezoelectric layer and the common electrode are sequentially formed on the dummy substrate.

The method may further include forming a conductive adhesive layer on the piezoelectric actuator.

The removing of the dummy substrate may be performed by any one of grinding, CMP (chemical mechanical planarization) and water jetting.

According to another aspect of the present invention, there is provided a method of manufacturing an inkjet head, the method including: forming a driving electrode and a piezoelectric layer on a dummy substrate; providing an inkjet head substrate having an ink passage therein and a common electrode layer formed at a top surface thereof; cutting the driving electrode and the piezoelectric layer into head cell units of the inkjet head substrate; bonding the dummy substrate to the inkjet head substrate so that the piezoelectric layer is arranged at a position corresponding to an ink chamber within the inkjet head substrate; and removing the dummy substrate.

According to another aspect of the present invention, there is provided a method of manufacturing an inkjet head, the method including: providing an inkjet head substrate having an ink passage therein; forming a film layer having an opening in a dummy substrate; forming a piezoelectric actuator in the opening; cutting the piezoelectric actuator into head cell units of the inkjet head substrate; processing the film layer to a thickness smaller than that of the piezoelectric actuator; bonding the dummy substrate to the inkjet head substrate so that the piezoelectric actuator and an ink chamber within the inkjet head substrate correspond to each other; and removing the dummy substrate and the film layer.

According to another aspect of the present invention, there is provided a method of manufacturing an inkjet head, the method including: forming a plurality of piezoelectric actuators on respective dummy wafers; cutting the plurality of piezoelectric actuators into head cell units of a plurality of inkjet heads; forming passages of the plurality of inkjet heads, including ink chambers formed at positions respectively corresponding to the plurality of piezoelectric actuators, on respective passage wafers; bonding the dummy wafers and the passage wafers to each other so that the piezoelectric actuators and the ink chambers correspond to each other; removing the dummy wafer; and cutting the dummy wafers and the passage wafers bonded to each other into inkjet head chip units.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1 through 11 are cross-sectional views illustrating a method of manufacturing an inkjet head according to an exemplary embodiment of the present invention; and

FIGS. 12 through 16 are cross-sectional views illustrating a method of manufacturing an inkjet head according to another exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. While those skilled in the art could readily devise many other varied embodiments that incorporate the teachings of the present invention through the addition, modification or deletion of elements, such embodiments may fall within the scope of the present invention.

In the drawings, the same or like reference numerals will be used throughout to designate the same or like components.

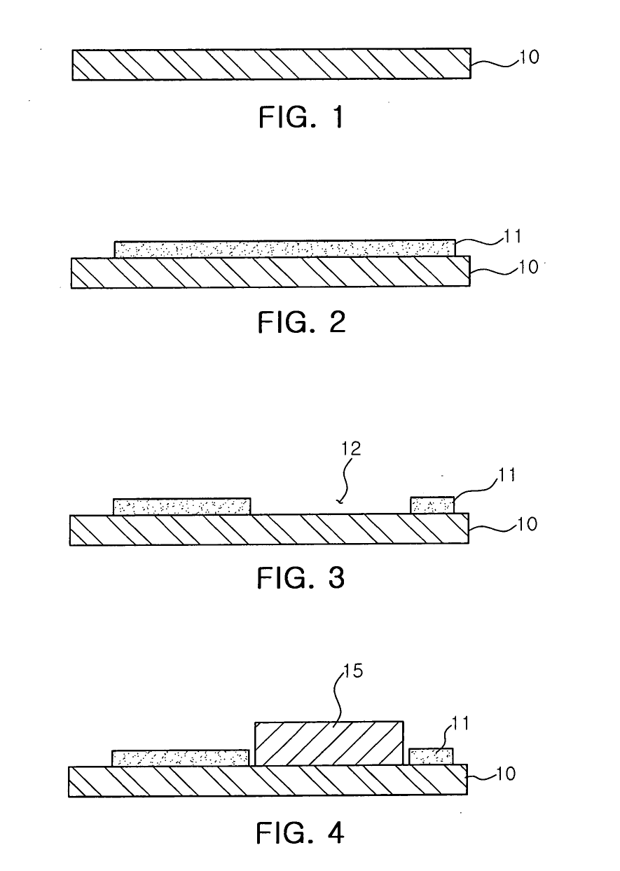

FIGS. 1 through 11 are cross-sectional views illustrating an inkjet head according to an exemplary embodiment of the invention. Hereinafter, a method of manufacturing an inkjet head according to an exemplary embodiment of the invention will be described in detail with reference to FIGS. 1 through 11.

First, a method of manufacturing an inkjet head according to a preferred embodiment of the invention will be described in brief. A dummy substrate having a piezoelectric actuator formed thereon and an inkjet head substrate having an ink passage therein are individually manufactured, the dummy substrate is bonded to the inkjet head substrate at wafer level, and the dummy substrate is then removed, thereby completing an inkjet head according to an exemplary embodiment of the invention. The processes of manufacturing a dummy substrate and an inkjet head substrate may be performed regardless of order. That is, any one of the dummy substrate and the inkjet head substrate may be manufactured earlier than the other, or the dummy substrate and the inkjet head substrate may be manufactured at the same time. For convenience of explanation, the process of manufacturing a dummy substrate will be first described.

As shown in FIG. 1, a dummy substrate 10 is prepared. Since the dummy substrate 10 is removed after the dummy substrate 10 is bonded to an inkjet head substrate, a substrate formed of a material, which can be easily removed and can readily form a piezoelectric actuator, may be used. For example, a material equal to a material forming a substrate used to manufacture an inkjet head, such as a silicon wafer, may be used. Besides, a glass wafer may be used therefor.

Then, as shown in FIG. 2, a film layer 11 is formed on the dummy substrate 10. The film layer 11 is a sacrificial layer that is provided in order to form a piezoelectric actuator. For example, a photoresist or a dry film resist (DFR) may be used. The film layer 11 may have a thickness of approximately 5 μm to 20 μm. Here, in the case that the film layer 11 has a thickness of 10 μm or more, the film layer 11 has edges thicker than the middle. Thus, the thick edges of the film layer 11 may be thinned by using EBR (edge bevel removal).

The film layer 11 may be formed of one or more layers. When a piezoelectric actuator is cut in units of head cell unit of an inkjet head, a lower layer of the film layer 11 may be patterned to have a shape corresponding to the edge of the piezoelectric actuator according to individual head cells, and thus may serve as an auxiliary cutting layer.

Then, as shown in FIG. 3, the film layer 11 is patterned to form an opening 12 through which a piezoelectric actuator is formed. When the dummy substrate 10 is bonded to the inkjet head substrate, the film layer 11 is patterned to form the opening 12 at a determined position so that the piezoelectric actuator can be bonded at a position corresponding to ink chambers inside the inkjet head substrate. Here, the opening 12 may be slightly larger than a piezoelectric actuator to be inserted therein in order to facilitate the inserting and securing of the piezoelectric actuator. For example, the film layer 11 may be patterned to a large size of approximately 50 μm. The film layer 11 may be patterned by using photolithography including exposure and development.

When the film layer 11 is patterned to form the opening 12 therein, alignment marks displaying the boundary of a piezoelectric actuator corresponding to individual head cells may also be formed around the opening 12 by patterning in order to display cutting lines when a piezoelectric actuator 15 is cut into head cell units of the inkjet head.

Then, as shown in FIG. 4, the piezoelectric actuator 15 is formed in the opening 12. The piezoelectric actuator 15 provides a driving force in order to eject ink, introduced into the ink chambers of the inkjet head substrate, through nozzles. For example, the piezoelectric actuator 15 may include a lower electrode serving as a common electrode, a piezoelectric film being transformed according to whether voltage is applied or not, and an upper electrode serving as a driving electrode.

The lower electrode may be formed of a single conductive metallic material. Preferably, the lower electrode may be formed of two metallic thin films of titanium (Ti) and platinum (Pt). A piezoelectric film may be formed on the lower electrode and be formed of a piezoelectric material, preferably, lead zirconate titanate (PZT) ceramics. The upper electrode is formed on the piezoelectric film and may be formed of any one of Pt, Au, Ag, Ni, Ti, and Cu.

The piezoelectric actuator 15 may be formed by using various kinds of methods. For example, the piezoelectric actuator 15 may be assembled in such a manner that PZT may be processed as a chip unit and then inserted into the opening 12. The piezoelectric actuator 15 and the dummy substrate 10 are bonded to each other by heating and pressurizing processes. For example, a hot press machine having a heating temperature of 150° C. and a weight of 2.0 tons may be used. Here, a conductive adhesive, formed of a metal such as Ag, Cu, or Ni, may be used to bond the piezoelectric actuator 15 and the dummy substrate 10 to each other. Then, the film layer 11 is baked by performing hard bake and is subsequently cooled slowly at a temperature of 150° C. for more than 30 minutes.

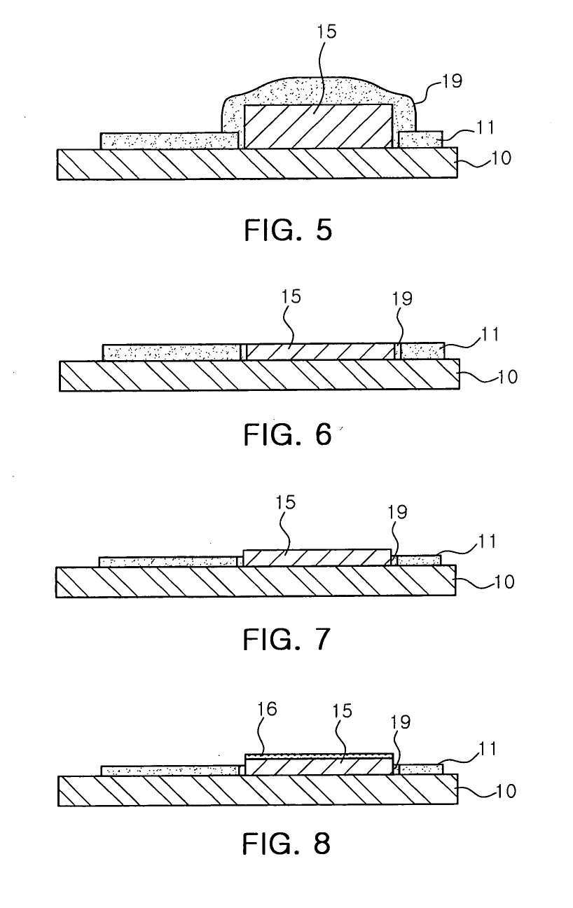

Then, as shown in FIG. 5, a photoresist 19 is coated over the dummy substrate 10. Here, a gap between the piezoelectric actuator 15 and the film layer 11 is also filled with the photoresist 19. The photoresist 19 fixes the piezoelectric actuator 15 and the film layer 11 by heating.

Then, as shown in FIG. 6, each of the piezoelectric actuator 15 and the film layer 11, coated with the photoresist 19, is polished to a designed thickness. For example, the piezoelectric actuator 15 is processed to a thickness of approximately 30 μm by grinding, polishing, or chemical mechanical polishing (CMP). The piezoelectric actuator 15 is cut into head cell units of the inkjet head.

The piezoelectric actuator 15 may be cut by dicing or using laser beams. When the film layer 11 is patterned to form alignment marks to display the positions of individual head cells in the piezoelectric actuator 15, the cutting of the piezoelectric actuator 15 is carried out on the basis of the patterned alignment marks. Furthermore, when the film layer 11 is formed of one or more layers and a lower layer of the film layer 11 serves as an auxiliary cutting layer, the piezoelectric actuator 15 may be cut along the marks formed by patterning the auxiliary cutting layer in order to display the boundary of the piezoelectric actuator corresponding to individual head cells.

Since the dummy substrate 10 is formed under the film layer 11 or the auxiliary cutting layer is interposed therebetween, the piezoelectric actuator 15 can be processed to a sufficient thickness covering processing errors when the piezoelectric actuator 15 is cut.

Then, as shown in FIG. 7, when the piezoelectric actuator 15, formed on the dummy substrate 10, is bonded above ink chambers of the inkjet head, each of the film layer 11 and the photoresist 19 is processed to a thickness smaller than that of the piezoelectric actuator 15 by ashing in order to reduce align errors and facilitate bonding.

Then, as shown in FIG. 8, an upper surface of the piezoelectric actuator 15 is coated with a conductive adhesive material 16, formed of a metal paste, such as a Ag, Cu or Ni paste. The coating of the conductive adhesive material 16 may be performed before the piezoelectric actuator 15 is cut into head cell units.

A method of manufacturing the inkjet head substrate 20 will now be described. The method of manufacturing the inkjet head substrate 20 includes processes of forming an ink passage in at least one wafer, which can be performed by using known methods. Hereinafter, a description will be made in brief on the basis of components forming an ink passage in an inkjet head substrate.

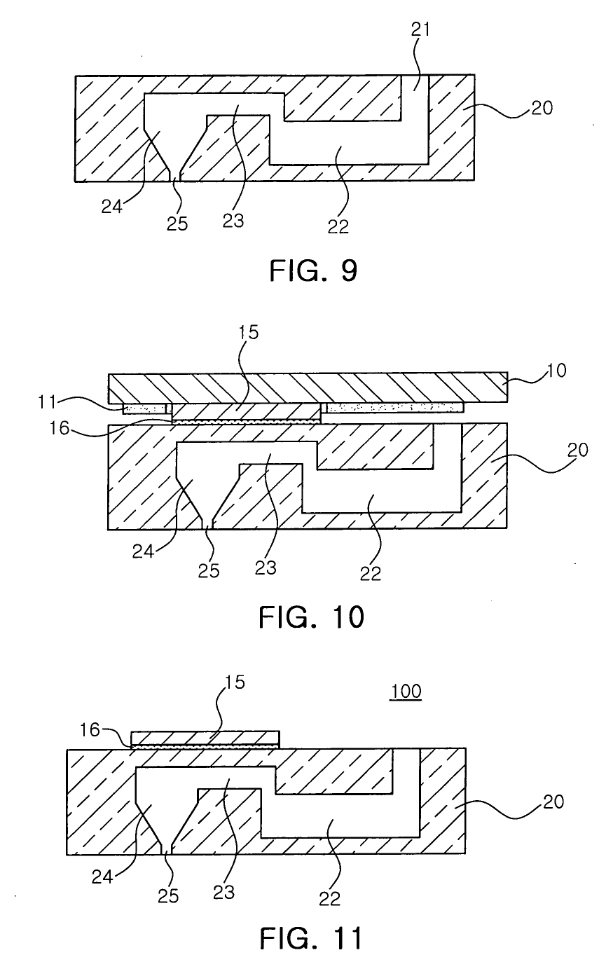

Referring to FIG. 9, an inkjet head substrate 20 may include an ink inlet 21 through which ink flows, a reservoir 22 storing the ink introduced through the ink inlet 21, a plurality of ink chambers 23 provided under the piezoelectric actuator 15 to be mounted, and a plurality of nozzles 25 through which the ink is ejected. A plurality of restrictors may be formed between the reservoirs 22 and the ink chambers 23 in order to prevent the ink within the ink chambers 23 from flowing backward into the reservoir 22 while the ink is ejected. Furthermore, the ink chambers 23 and the nozzles 25 may be connected to each other by a plurality of dampers 24.

The inkjet head substrate 20 may be formed in such a manner that the above-described components forming the ink passage are properly formed on upper and lower substrates, which are then bonded to each other by silicon-direct-bonding (SDB). Here, the upper substrate may be a single crystal silicon substrate or an SOI substrate, while the lower substrate may be an SOI substrate. Furthermore, the inkjet head substrate 20 is not limited thereto. An ink passage may be formed using more than two substrates, or an ink passage may be formed using a single substrate. Here, the above-described components forming the ink passage are taken as an example. Ink passages having different configurations may be prepared according to specifications and conditions being required.

Then, as shown in FIG. 10, the dummy substrate 10 is bonded to the inkjet head substrate 20 at wafer level. Specifically, the inkjet head substrate 20 and the dummy substrate 10 are arranged so that the piezoelectric actuator 15 of the dummy substrate 10 is located above the ink chambers 23 of the inkjet head substrate 20. Here, the upper surface of the dummy substrate 10 and the upper surface of the inkjet head substrate 20 are arranged to face each other. Then, the conductive adhesive material 16, formed on the upper surface of the piezoelectric actuator 15, is heated so that the piezoelectric actuator 15 is bonded to the upper surface of the inkjet head substrate 20.

Then, as shown in FIG. 11, the dummy substrate 10 is removed from a bonded wafer structure by grinding, water jetting or CMP. The film layer 11 and the photoresist 19 remaining around the piezoelectric actuator 15 are removed by air blowing or tape removing. After the dummy substrate 10, the film layer 11 and the photoresist 19 are removed, the inkjet head 100 is completed.

Since the inkjet head substrate 20 and the dummy substrate 10 are bonded at wafer level to thereby form the piezoelectric actuator 15, productivity can be improved, such as in a reduction in processing errors and shortened processing time in comparison with the method according to the related art in which a piezoelectric actuator is formed for each individual head cell.

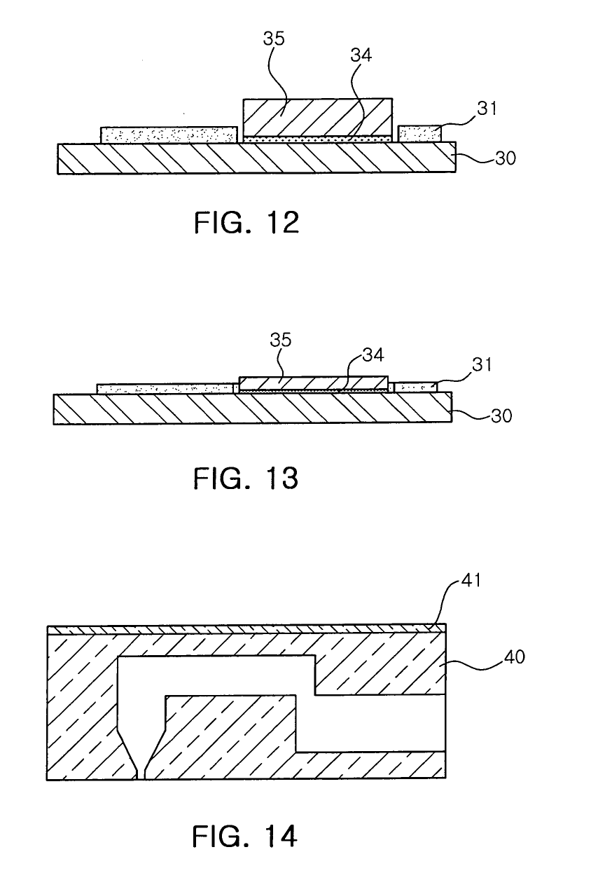

Hereinafter, a method of manufacturing an inkjet head according to another exemplary embodiment of the invention will be described. FIGS. 12 through 16 are cross-sectional views illustrating a method of manufacturing an inkjet head according to another exemplary embodiment of the invention.

When it comes to forming a piezoelectric actuator, a method of manufacturing an inkjet head according to this embodiment, as shown in FIGS. 12 through 16, is different from the method of manufacturing the inkjet head according to the above-described exemplary embodiment, as shown in FIGS. 1 through 11, in that a lower electrode, serving as a common electrode, is formed on the entire upper surface of an inkjet head substrate. Therefore, processes except for a process of forming a piezoelectric actuator are substantially the same as those of the method of manufacturing the inkjet head according to the embodiment as shown in FIGS. 1 through 11. Thus, a detailed description thereof will be omitted, and a description will be made mainly on differences therebetween.

Referring to FIG. 12, a film layer 31 is coated over a dummy substrate 30 and is then patterned to form an opening therein. Subsequently, a driving electrode 34 and a piezoelectric film 35 of a piezoelectric actuator are sequentially formed. Here, the film layer 31 may be patterned to form alignment marks thereon in order to separate the piezoelectric actuator according to individual head cells. When the film layer 31 is formed of one or more layers, a lower layer of the film layer 31 may be patterned to form the alignment marks.

Then, as shown in FIG. 13, each of the piezoelectric film 35 and the film layer 31 is polished to a designed thickness. After the piezoelectric film 35 and the driving electrode 34 are cut into head cell units of an inkjet head, the film layer 31 is processed to a thickness smaller than that of the piezoelectric film 35.

Here, the piezoelectric film 35 and the film layer 31 may be processed to the above-described thicknesses by grinding, polishing or chemical mechanical polishing (CMP). The piezoelectric film 35 and the driving electrode 34 may be cut by dicing or using laser beams. The film layer 31 may be processed by ashing.

In terms of cutting the piezoelectric film 35 and the driving electrode 34, in the case that the film layer 31 is patterned to form alignment marks to display positions of individual head cells in the piezoelectric film 35, the cutting process is carried out on the basis of the alignment marks formed by patterning. Furthermore, when the film layer 31 is formed of one or more layers, and the lower layer of the film layer 31 serves as an auxiliary cutting layer, cutting may be carried out along marks formed by patterning the auxiliary cutting layer in order to display the boundary of the piezoelectric film corresponding to the individual head cells.

Since the dummy substrate 30 is formed under the film layer 31 or the auxiliary cutting layer is interposed therebetween, the cutting of the piezoelectric film 35 can be carried out to a sufficient thickness covering processing errors.

Then, as shown in FIG. 14, an inkjet head substrate 40 having an ink passage therein is prepared, and a lower electrode 41 serving as a common electrode of a piezoelectric actuator is formed on the inkjet head substrate 40. Here, the lower electrode 41 may be formed on the entire surface of the inkjet head substrate 40 and may be formed of a single conductive metallic material. However, preferably, the lower electrode 41 may be formed of two metallic thin layers of titanium (Ti) and platinum (Pt). The lower electrode 41 serves as both a common electrode and a diffusion barrier layer preventing interdiffusion between a piezoelectric film and the inkjet head substrate 40.

The inkjet head substrate 40 includes a reservoir, ink chambers, restrictors, dampers, and nozzles along the ink passage and may be formed of at least one wafer.

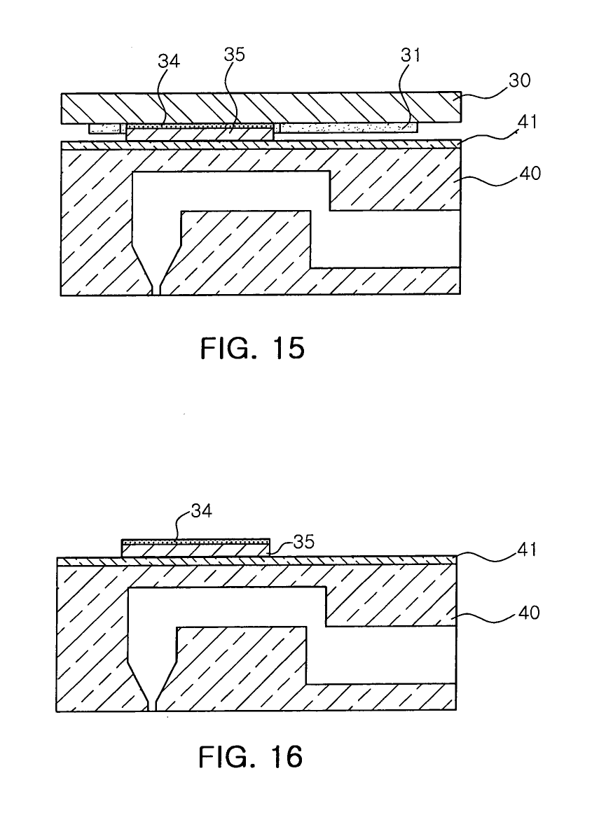

As shown in FIG. 15, the dummy substrate 30 is then bonded to the inkjet head substrate 40 at wafer level. Specifically, the inkjet head substrate 40 and the dummy substrate 30 are arranged so that the piezoelectric film 35 of the dummy substrate 30 is arranged above the ink chambers of the inkjet head substrate 40. Here, the dummy substrate 30 and the inkjet head substrate 40 are arranged so that the upper surface of the dummy substrate 30 and the upper surface of the inkjet head substrate 40 face each other, and the piezoelectric film 35 and the lower electrode 41 are bonded to each other. Here, the piezoelectric film 35 and the lower electrode 41 may be bonded to each other by using a conductive adhesive material.

Then, as shown in FIG. 16, the dummy substrate 30 is removed from a bonded wafer structure by performing grinding, water jetting or CMP. The film layer 31 remaining around the piezoelectric film 35 and the driving electrode 34 is removed by air blowing or tape removing. After the dummy substrate 30 and the film layer 31 are removed, an inkjet head is completed.

As described above, according to a method of manufacturing an inkjet head according to an exemplary embodiment of the invention, since a piezoelectric actuator is formed at wafer level, errors occurring when processing the piezoelectric actuator can be reduced, processing time can be shortened, flexural deformation of an inkjet head substrate occurring when the piezoelectric actuator is cut into head cell units, and thickness variations of cut portions can be prevented, thereby improving processing precision and productivity.

The description has been made in association with the processes of manufacturing a single inkjet head. However, the invention is not limited thereto. A plurality of inkjet heads and a plurality of piezoelectric actuators are formed on individual wafers in an array method, which are then bonded to each other and are cut into head chip units. Hereinafter, these processes will be described in detail. However, the processes of forming an ink passage in an inkjet head substrate and forming a piezoelectric actuator in a dummy substrate according to the above-described embodiments are substantially the same as those of this embodiment. Thus, a detailed description of those processes will be omitted for convenience of explanation.

First, a process of forming a plurality of inkjet heads and a plurality of piezoelectric actuators on wafers according to an array method will be described in brief. A plurality of inkjet heads are formed on passage wafers using an array method, and a plurality of piezoelectric actuators are formed on dummy wafers using an array method. The passage wafers and the dummy wafers are bonded to each other so that ink chambers of the inkjet heads and the piezoelectric actuators correspond to each other. The passage wafers and the dummy wafers bonded to each other are cut into head chip units, thereby completing inkjet heads.

According to a method of forming a plurality of inkjet heads on passage wafers, the same inkjet heads as described above in connection with the above-described embodiments of the invention, that is, inkjet heads each having an ink inlet through which ink flows, a reservoir storing the ink introduced through the ink inlet, a plurality of ink chambers located under a piezoelectric actuator to be mounted, and a plurality of nozzles through which the ink is ejected are arrayed on a plurality of passage wafers.

According to a method of forming a plurality of piezoelectric actuators on dummy wafers, the same piezoelectric actuators as described above in connection with the above-described embodiments of the invention are arrayed on a plurality of dummy wafers. Specifically, after a film layer is formed on the plurality of dummy wafers, the film layer is patterned to form a plurality of openings through which a plurality of piezoelectric actuators are individually formed. The piezoelectric actuators are then formed in the plurality of openings, and the piezoelectric actuators are cut into head cell units.

Then, the passage wafers having the plurality of inkjet heads arrayed thereon and the dummy wafers having the plurality of piezoelectric actuators arrayed thereon are bonded to each other. Here, as for the individual ink passages of the plurality of inkjet heads, the passage wafers and the dummy wafers are bonded to each other so that the piezoelectric actuators correspond to the ink chambers. The passage wafers and the dummy wafers bonded to each other are cut into inkjet head chip units, and the dummy wafers and the film layer are removed, thereby completing inkjet head chips. Here, alternatively, after the dummy wafers and the film layer are removed, the passage wafers and the dummy wafers bonded to each other are then cut into inkjet head chip units, thereby completing inkjet head chips.

In comparison with the method in the related art by which only a passage of an inkjet head is formed at wafer level, and each individual piezoelectric actuator is then formed on the upper surface of the passage, a method according to an exemplary embodiment of the invention can improve productivity by forming a plurality of inkjet heads and a plurality of piezoelectric actuators on individual wafers according to an array method, bonding the inkjet heads and the piezoelectric actuators to each other, and cutting the inkjet heads and the piezoelectric actuators, bonded to each other, into head chip units. Furthermore, a piezoelectric actuator is also formed at wafer level, and wafers are bonded to each other and then cut into head chip units, thereby improving processing precision and location precision of a piezoelectric actuator as well as enhancement in productivity.

As set forth above, according to exemplary embodiments of the invention, according to a method of manufacturing an inkjet head, a piezoelectric actuator is bonded to an inkjet head at wafer level, thereby enhancing productivity such as improving processing precision, reducing manufacturing costs and reducing processing time.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing an inkjet head, the method comprising:
forming a piezoelectric actuator on a dummy substrate;
cutting the piezoelectric actuator into head cell units of an inkjet head;
preparing an inkjet head substrate including an ink chamber formed at a position corresponding to the piezoelectric actuator;
bonding the dummy substrate and the inkjet head substrate to each other so that the piezoelectric actuator and the ink chamber correspond to each other; and
removing the dummy substrate.

2. The method of claim 1, wherein the forming of the piezoelectric actuator on the dummy substrate comprises:
forming a film layer on the dummy substrate, the film layer having an opening in which the piezoelectric actuator is formed;
inserting the piezoelectric actuator in the opening; and
removing the film layer.

3. The method of claim 2, wherein the film layer is formed of one or more layers, and a lower layer of the film layer serves as an auxiliary cutting layer when the piezoelectric actuator is cut into head cell units of the inkjet head.

4. The method of claim 2, wherein an alignment mark is formed on the film layer to display a position of each individual head cell in the piezoelectric actuator.

5. The method of claim 2, wherein the film layer is formed of DFR (dry film resist).

6. The method of claim 1, further comprising heating and pressurizing the dummy substrate and the piezoelectric actuator.

7. The method of claim 1, further comprising polishing the piezoelectric actuator.

8. The method of claim 1, further comprising cutting the piezoelectric actuator so that respective cut piezoelectric actuators are formed according to unit head cells of the inkjet head substrate.

9. The method of claim 1, wherein the forming of the piezoelectric actuator on the dummy substrate is performed by any one of sputtering, electron beam evaporation, thermal evaporation, screen printing and bulk ceramic bonding.

10. The method of claim 1, wherein the piezoelectric actuator comprises a driving electrode, a piezoelectric layer and a common electrode, and the driving electrode, the piezoelectric layer and the common electrode are sequentially formed on the dummy substrate.

11. The method of claim 1, further comprising forming a conductive adhesive layer on the piezoelectric actuator.

12. The method of claim 1, wherein the removing of the dummy substrate is performed by any one of grinding, CMP (chemical mechanical planarization) and water jetting.

13. A method of manufacturing an inkjet head, the method comprising:
forming a driving electrode and a piezoelectric layer on a dummy substrate;
providing an inkjet head substrate having an ink passage therein and a common electrode layer formed at a top surface thereof;
cutting the driving electrode and the piezoelectric layer into head cell units of the inkjet head substrate;
bonding the dummy substrate to the inkjet head substrate so that the piezoelectric layer is arranged at a position corresponding to an ink chamber within the inkjet head substrate; and
removing the dummy substrate.

14. A method of manufacturing an inkjet head, the method comprising:
providing an inkjet head substrate having an ink passage therein;
forming a film layer having an opening in a dummy substrate;
forming a piezoelectric actuator in the opening;
cutting the piezoelectric actuator into head cell units of the inkjet head substrate;
processing the film layer to a thickness smaller than that of the piezoelectric actuator;
bonding the dummy substrate to the inkjet head substrate so that the piezoelectric actuator and an ink chamber within the inkjet head substrate correspond to each other; and
removing the dummy substrate and the film layer.

15. A method of manufacturing an inkjet head, the method comprising:
forming a plurality of piezoelectric actuators on respective dummy wafers;
cutting the plurality of piezoelectric actuators into head cell units of a plurality of inkjet heads;
forming passages of the plurality of inkjet heads, including ink chambers formed at positions respectively corresponding to the plurality of piezoelectric actuators, on respective passage wafers;
bonding the dummy wafers and the passage wafers to each other so that the piezoelectric actuators and the ink chambers correspond to each other;
removing the dummy wafer; and
cutting the dummy wafers and the passage wafers bonded to each other into inkjet head chip units.
